(19) United States
(12) Patent Application Publication
(10) Pub. No.: US 2020/0002235 A1
(43) Pub. Date: Jan. 2, 2020

(54) CYLINDRICAL TITANIUM OXIDE SPUTTERING TARGET AND PROCESS FOR MANUFACTURING THE SAME

(71) Applicant: Materion Advanced Materials Germany GmbH, Alzenau (DE)

(72) Inventors: Markus Schultheis, Flieden (DE); Christoph Simons, Biebergmünd (DE); Martin Schlott, Offenbach (DE)

(21) Appl. No.: 16/489,017

(22) PCT Filed: Mar. 5, 2018
(86) PCT No.: PCT/EP2018/055357

§ 371 Date: Aug. 27, 2019

(30) Foreign Application Priority Data
Mar. 14, 2017 (EP) 17160921.7

(51) Int. Cl. C04B 35/46; C04B 35/653; C23C 14/34; C23C 4/11; C23C 4/134; C23C 4/16

(52) U.S. Cl. CPC C04B 35/46; C04B 35/653; C23C 14/3414; C23C 4/11; C23C 4/134; C04B 2111/805; C04B 2235/3237; C04B 2235/5418; C04B 2235/79; C04B 2235/80; C04B 2235/96; C23C 4/16

(57) ABSTRACT

Known cylindrical sputtering targets comprise a substrate and a target material that forms a layer on the substrate, said layer has a thickness d, wherein the target material comprises TiOx as the main component, and x is within a range of 1<x<2. Starting therefrom and in order to provide large-sized cylindrical sputtering targets with a thick target layer comprising sub-stoichiometric TiO₂ it is proposed that x is within a range of 1.45<x<1.7 that allows a target layer thickness d which is larger than 10 mm.

### TECHNICAL FIELD

The present invention relates to a cylindrical sputtering target comprising a substrate and a target material that forms a layer on the substrate, said layer has a thickness d, wherein the target material comprises TiOx as the main component, and x is within a range of 1<x<2.

The invention further relates to a process for producing a sputtering target, said process comprises
(a) providing a substrate made of a metal or alloy,
(b) providing a ceramic powder comprising a metal oxide powder of the chemical formula TiOy as the main component, whereby TiOy is deficient in oxygen as compared with the stoichiometric composition TiO₂, and
(c) forming a ceramic layer on the substrate by plasma spraying, wherein said ceramic powder is made in a semi-molten state in a high temperature plasma gas in a reducing atmosphere, and it is transported and deposited onto the substrate by the plasma gas so as to obtain a target comprising a layer with a thickness d of a target material that comprises TiOx as the main component, whereby TiOx is deficient in oxygen as compared with the stoichiometric composition TiO₂.

Sputter target are used for forming transparent titanium dioxide films having a high refractive index (n=2.4) by direct current (DC) sputtering for heat reflecting glasses, antireflection films, interference filters, polarizing films and photocatalytic films, as well as for multi-layer stacks having an antistatic, heat reflecting or electromagnetic wave shielding function, such glasses are used for example for buildings or automobiles, CRT or a flat displays.

There are different types of sputtering targets, such as planar magnetron and cylindrical rotatable magnetron targets. Planar magnetrons may have an array of magnets arranged in the form of a closed loop and mounted in a fixed position behind the target. For sputtering over a large area, e.g. for a glass sheet for buildings, usually a magnetron type rotary cathode made of a hollow cylindrical target is required. A magnetic field is generated from the inside of the inner bore of the cylindrical target and sputtering is carried out while rotating the target and cooling the target from inside. By the use of such a cylindrical target, a large power per unit area can be applied as compared with a planer type target, whereby film formation at a high speed is possible.

A cylindrical rotatable magnetron sputtering target typically includes a substrate tube within which is the magnet array.

### PRIOR ART

Among various sputtering methods, DC sputtering utilizing direct current discharge is suitable for forming a uniform film over a substrate having a large area. When a high refractive index titanium oxide film is to be formed by DC sputtering, a so-called reactive sputtering is employed wherein a metallic target having electroconductivity is subjected to sputtering in a reactive or partially reactive gas atmosphere containing oxygen.

However, there has been a problem that the film-forming speed of a thin film obtainable by this method is very slow, whereby the productivity is poor, and the cost tends to be high. To solve that problem EP 871 794 B1 proposes using a target which comprises a metallic substrate covered by a layer of an electrical conductive target material comprising TiOx as the main component, wherein x is within a range of 1<x<2, that means it is deficient in oxygen as compared with the stoichiometric composition TiO₂. Sub-stoichiometric titanium dioxide, TiOx, where x is in the range of from 1.55 to 1.95 is known in the art. Depending upon the stoichiometry the electrical conductivity will vary. Due to its conductivity the sub-stoichiometric TiOx target material is suitable for DC sputtering in a mixed gas atmosphere of argon and oxygen.

The target material may be formed by spraying or sintering and bonding it onto the outer surface of the substrate tube. EP 871 794 B1 proposes a process which comprises plasma spraying titanium dioxide (TiO₂) powder optionally together with niobium oxide, onto a rotatable substrate tube in an atmosphere which is oxygen deficient and which does not contain oxygen-containing compounds. The molten sub-stoichiometric TiOx is solidified onto the substrate by cooling under conditions which prevent the sub-stoichiometric titanium dioxide from combining with oxygen.

In another process for providing a sub-stoichiometric TiOx sputtering target capable in high-output direct-current (DC) sputtering without generating target cracks, JP 2016-017196 A proposes a sputtering target material having a TiOx composition, where 1.8<x<1.9. The sputtering target material is formed of a sintered body obtained by sintering a mixed powder obtained by mixing 95-99 wt.-% of the total amount of TiO₂ with 1 to 5 wt.-% of a metallic titanium powder.

### OBJECT OF THE INVENTION

Use of rotating cylindrical magnetrons instead of planar magnetrons has several advantages. A cylindrical target may contain more target material and it has a superior utilization yield, which results in much longer production runs and reduced downtime of the machine. Because the heat load is divided equally over the circumference of the target a higher power density can be applied thereby resulting in an increased deposition speed.

Plasma spraying is a coating process using plasma as a heat source to semi-melt feedstock materials, typically in powder form. The high process temperatures allow the ceramic titanium oxide to be melted; the resulting heated droplets are accelerated by process gases and propelled towards the substrate, e.g. a backing tube of a cylindrical target. Upon impact, the droplets are deformed to splats and solidify rapidly to form a coating or layer. The high cooling rates result in a conductive TiOx material.

Plasma spraying is characterized by a high deposition rate. Because of the high cooling rates of the process the backing tube is hardly affected by any thermal interaction with the molten droplets so no diffusion layer between the substrate and the coating is formed. This means that the target material preserves its desired composition over the whole layer thickness and maximizes the utilization of target material for sputter deposition. Because of these advantages, plasma spraying of the target material onto the outer surface of the cylindrical substrate is a preferred method to produce sputter targets.

However, the maximum layer thicknesses applied by those coating processes is typically limited to 10 millimeters. That limitation narrows the advantage concerning utilization yield, longer production runs and reduced downtime of the machine. A possible reason for that limitation is that troubles are likely to occur such as cracking of the target layer and peeling off. In addition to that brittle fractures in the target layer was observed at high power levels.

Accordingly, it is an object of the present invention to provide an improved process for the production of large-sized cylindrical sputtering targets comprising sub-stoichiometric TiO₂, which can be used as targets at high power levels.

Furthermore, it is an object of the invention to provide large-sized cylindrical sputtering targets comprising sub-stoichiometric TiO₂ with a target layer thickness of more than 10 mm.

### SUMMARY OF THE INVENTION

The Sputtering Target of the Invention

Starting from a generic type sputtering target as specified above, the object is achieved in accordance with the invention in that the target layer thickness d is larger than 10 mm and x is within a range of 1.45<x<1.7.

Surprisingly, it was found that the 10 mm limitation of target layer thickness d can be overcome if the grade of sub-stoichiometry of the TiOx is increased so that x is below 1.7. The above object concerning a large-sized cylindrical sputtering targets comprising sub-stoichiometric TiO₂, which can be used as targets at high power levels can be met if at the same time, the following features are fulfilled:
(1) the target layer is produced by plasma spraying,
(2) the grade of sub-stoichiometry of the TiOx is higher than usual so that x is in the range between 1.45 and 1.7, and more preferred x is in the range between 1.50 and 1.65 and most preferred x<1.55,
(3) the layer thickness over at least a part of the length of the substrate is larger than 10 mm, preferably at least 12 mm, more preferred at least 14 mm, and most preferred it is at least 16 mm.

The substrate onto which the target layer is deposited may be a substrate tube made of a metal or a metal alloy like stainless steel, and often it has one or more top coatings or an undercoat layer for improving the bonding of the target material; the undercoat layer may have a thermal expansion coefficient intermediate between the thermal expansion coefficient of the TiOx layer and the thermal expansion coefficient of the substrate, and/or a layer having a thermal expansion coefficient close to the thermal expansion coefficient of the TiOx layer and/or a layer having a higher ductility compared to the material of the substrate and/or the target material.

The main component of the target material being TiOx means that additives like niobium oxide, zirconia or yttrium oxide may be present in small amounts but in total less than 50 atom-% of the target material. The share of TiOx is more than 50 atom-%, preferably it is more than 75 atom-%, more preferred it is more than atom-90% and most preferred the target material completely consists of TiOx.

Sub-stoichiometric titanium dioxide TiOx, where x is in the range of from 1.45 to less than 1.7 has a high electrical conductivity so that the target material is suitable for sputtering sub-stoichiometric and stoichiometric TiO₂ layers in a reactive or partially reactive DC sputtering process, for example using mixed gas atmosphere of argon and oxygen. It was found that sputtering targets with such thick target layers show a reduced susceptibility to cracking even when they are processed at high power levels up to 15 kW/m.

Furthermore, when compared to conventional target layers made of sub-stoichiometric titanium dioxide TiOx, target layers according to the invention made of sub-stoichiometric titanium dioxide TiOx, where x is in the range of from 1.45 to less than 1.7 show stronger bonding and better heat transfer to the substrate both in the production of the target layer and during the sputtering process, so that no peeling off occurs.

It has been found advantageous when the target material has a Vickers hardness HV, wherein HV<500 HV10, preferably HV<475 HV10.

Here, the unit “HV10” represents the Vickers hardness (HV), evaluated using a Vickers hardness testing machine applying a 10 kilopond load. The method for measuring hardness according to Vickers is specified in DIN EN ISO 6507-1. Testing methods for the evaluation of the micro hardness of metallic coatings are specified in DIN ISO 4516. To convert a Vickers hardness number into MPa (SI units) one multiplies by 9.807.

A hardness degree of HV<500 HV10 is low when compared to conventional target layers made of sub-stoichiometric titanium dioxide. A low hardness reduces the target layer's susceptibility to brittle cracks.

In the ideal case, the sputtering target according to invention is free from any visible surface cracks; if any surface cracks exist, they show hair-crack characteristics with a web-like structure with a maximum web-cell size less than 1 cm.

The target layer made of sub-stoichiometric titanium oxide TiOx, where x is in the range of from 1.45 to 1.7, preferably where x in the range between 1.50 and 1.65, most preferred x<1.55 shows crystalline phases and a phase concentration distribution which advantageous affects brittleness and bonding strength of the target material.

One embodiment of the target material comprises a Ti₄O₇ phase in a concentration of at least 30 vol.-%, and a Ti₃O₅ phase in a concentration of at least 40 vol.-%, wherein preferably the sum of the concentration of the Ti₄O₇ and Ti₃O₅ phases is at least 75 vol.-%, most preferred at least 99 vol.-%.

The sputtering target according to any one of claims 1 to 6, wherein the target material comprises a Ti₃O₅ phase in a first concentration (in vol.-%) and a Ti₄O₇ phase in a second concentration (in vol.-%), wherein the ratio of first concentration and second concentration [Ti₃O₅]/[Ti₄O₇] is at least 1.2, preferably the ratio [Ti₃O₅]/[Ti₄O₇] it is at least 1.4.

In a further preferred embodiment of the invention, the target material comprises an Anatas phase of TiO₂ in a total concentration of less than 1 vol.-%.

It has proved beneficial if the degree of sub-stoichiometry, represented by the x-value in TiOx, is constant over the volume of the target layer. In view of that a preferred sputtering target material comprises a homogeneous degree of sub-stoichiometry, in the sense that the degree of sub-stoichiometry of ten samples of 10 g each has a standard deviation in the of sub-stoichiometry degree of less than ±5%.

The Process of the Invention

Starting from the process of the generic type specified at the outset, the above-mentioned object is achieved in accordance with the invention, in that said metal oxide powder TiOy is within a range of 1.3<y<1.7, and wherein x in said target material TiOx is within a range of 1.45<x<1.7, and the layer thickness d is more than 10 mm.

According to the invention, a ceramic target layer is deposited on a substrate by plasma spraying of a ceramic starting powder. The sub-stoichiometric composition of the TiOx material of the target layer is characterized by 1.45<x<1.7. Generally, the starting powder may have the same sub-stoichiometric composition as the material of the target layer. However, it was observed that a certain oxidation of titanium may occur during plasma spraying, especially at the high end of the oxygen deficiency (around y=1.45). Therefore, preferably the starting TiOy powder material may have a higher grade of oxygen deficiency than the resulting target material, especially at the high end of the oxygen deficiency. Therefore, the starting ceramic TiOy powder is characterized by a sub-stoichiometric composition, whereby: 1.3<y<1.7.

Surprisingly, it was found that the usual 10 mm limitation of target layer thickness d can be overcome if the grade of sub-stoichiometry of the TiOx of the target material is increased so that x is below 1.7. The above object concerning the process for manufacturing a large-sized cylindrical sputtering target comprising sub-stoichiometric TiO₂, which can be used as targets at high power levels, can be met if at the same time, the following features are fulfilled:
(1) the target layer is produced by plasma spraying a ceramic metal oxide powder of the chemical formula TiOy as the main component, whereby TiOy is deficient in oxygen as compared with the stoichiometric composition TiO₂, whereby: 1.3<y<1.7. Preferably, for plasma spraying an oxygen deficient titanic powder is provided having a particle size in the range of from 25-125 μm, preferably in the range of from 40-90 μm.
(2) The grade of sub-stoichiometry of the TiOx is higher than usual so that x is in the range between 1.45 and 1.7, and more preferred x is in the range between 1.50 and 1.65 and most preferred x<1.55.
(3) The layer thickness of the target layer over at least a part of the length of the substrate is larger than 10 mm, preferably at least 12 mm, more preferred at least 14 mm, and most preferred it is at least 16 mm.

The substrate onto which the target layer is deposited may be a substrate tube made of a metal or a metal alloy like stainless steel, and often it has one or more top coatings or an undercoat layer for improving the bonding of the target material; the undercoat layer may have a thermal expansion coefficient intermediate between the thermal expansion coefficient of the TiOx layer and the thermal expansion coefficient of the substrate, and/or a layer may have a thermal expansion coefficient close to the thermal expansion coefficient of the TiOx layer, and/or a layer having a ductility which is higher than that of the material of the substrate tube and/or higher than that of the target material.

Sub-stoichiometric titanium dioxide TiOx, where x is in the range of from 1.45 to less than 1.7 has a high electrical conductivity so that the target material is suitable for sputtering sub-stoichiometric and stoichiometric TiO₂ layers in a reactive or partially reactive DC sputtering process, for example using mixed gas atmosphere of argon and oxygen. It was found that sputtering targets with such thick target layers show a reduced susceptibility to cracking even when they are processed at high power levels up to 15 kW/m.

Furthermore, when compared to conventional target layers made of sub-stoichiometric titanium dioxide TiOx, target layers according to the invention made of sub-stoichiometric titanium dioxide TiOx, where x is in the range of from 1.45 to less than 1.7 show stronger bonding and better heat transfer to the substrate both in the production of the target layer and during the sputtering process, so that no peeling off occurs.

### Measuring Methods

Vickers Hardness Test

For preparation test samples are embedded in a resin on basis of methylmetacrylate. After hardening a metallographic preparation including grinding down to a diamond grain size of 1200 mesh and a final polishing is made so that the sample to be tested is free of streaks. The Vickers hardness test method consists of indenting the test sample with a diamond indenter, in the form of a pyramid with a square base and an angle of 136 degrees. The intender is pressed vertically into the surface of the sample using a test load F. The full load is normally applied for 10 to 15 seconds. The two diagonals of the indentation left in the surface of the material after removal of the load are measured using a microscope and their average calculated. From that value the Vickers hardness can be calculated or it can be metered from a Vickers HV hardness table.

Phase Analysis and Determination of the Phase Content

Test samples are powdered using a mortar. The powders are irradiated by a two circle goniometer Stadi P of the company Stoe & Cie in transmission mode with X-rays CuK alpha 1(=1.54056 Angstrom). The linear position-sensitive detector (LPSD) is used with a range of 6.60° between 2 theta (3,000° to)79,990°, step size 0.010. The measuring duration is 240 seconds in increments of 0.55° (20 sec/step), so the entire measurement lasts 6.47 hours. The used generator operates at a voltage of 40 kV and at a current of 30 mA. Adjustment and calibration of the instrument is based on the NIST standard Si (640 d). The volume fractions of the respective phases have been determined as follows:

The diffraction diagrams are evaluated by using a software “Rietveld SiroQuant®, version V4.0” purchased from Sietronics Pty Ltd. The respective phase contents in the test samples are calculated in shares per volume.

Determination of the Reduction Degree (x-value in TiOₓ)

The x-value in TiOₓ is determined by taking five samples of about 10 g from the target and the starting powder respectively. The sample material is pulverized in a mortar to a particle size of less than 10 μm. The thus obtained powder is annealed in pure oxygen at 1100° C. for 1 hour. For powder samples the pulverization step may be omitted if the particle size of the starting powder is already less than 10 μm. The weight increase caused by that treatment is measured. The x-value representing the oxygen stoichiometry in the formula TiOₓ is then determined from the average weight increase ΔG (ΔG=m(TiO₂)−m(TiOₓ)) from the at least 5 measurements in grams as follows:

x=2−[ΔG*M(TiO₂)]/[m(TiO₂)*M(O)]

where M(TiO₂) is the molar mass of stoichiometric TiO₂(=79,87g/mol)
M(O) is the molar mass of elemental oxygen(=16 g/mol)
m(TiOₓ) is the sample weight in grams measured prior to annealing.
m(TiO₂) is the sample weight in grams measured after annealing.

Measuring the Adhesive Strength of the Target Layer on a Backing Tube

An impact hammer test is used to determine the adhesive strength of the target layer. Laminated specimens with the compositions of TiO_{1.8} and TiO_{1.6} are produced by plasma spraying on stainless steel substrate including an undercoating of nickel metal in analogy to the production of the target tubes of examples 1 and 2. The sprayed bands have a thickness of 6 mm and a width of 250 mm.

The hammer impact test is carried out by striking an hammer onto the surface of the specimens, the hammer coming from the same height and hits the surface at the same speed. After the impact the surface is tested for any cracks by using the ethanol visualization test.

Ethanol Visualization Test

For proving a crack free surface an ethanol visualization test is used. Liquid ethanol is injected onto the test sample so that it is completely covered with ethanol. Due to a faster evaporation of ethanol on the plane surface of the sample compared to the ethanol evaporation in the cracks, a visible color difference occurs (dark/bright), so that any existing cracks are visible as dark vein-like lines or cross-shaped patterns. A target material is defined as being free of cracks if it contains no crack with a total length of more than 1 cm.

### PREFERRED EMBODIMENTS OF THE INVENTION

The invention will now be explained in more detail with reference to a patent drawing and an embodiment. In detail,

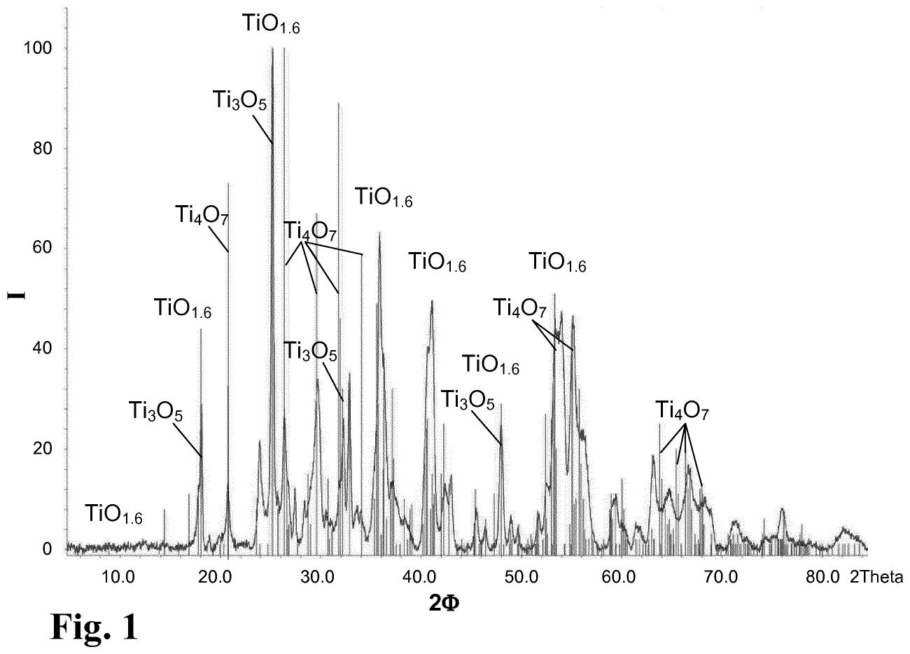

FIG. 1 shows an X-ray diffraction diagram of a target layer material according to the invention in combination with the typical deflection signals of Ti₃O₅ and Ti₅O₇ crystalline phases, and

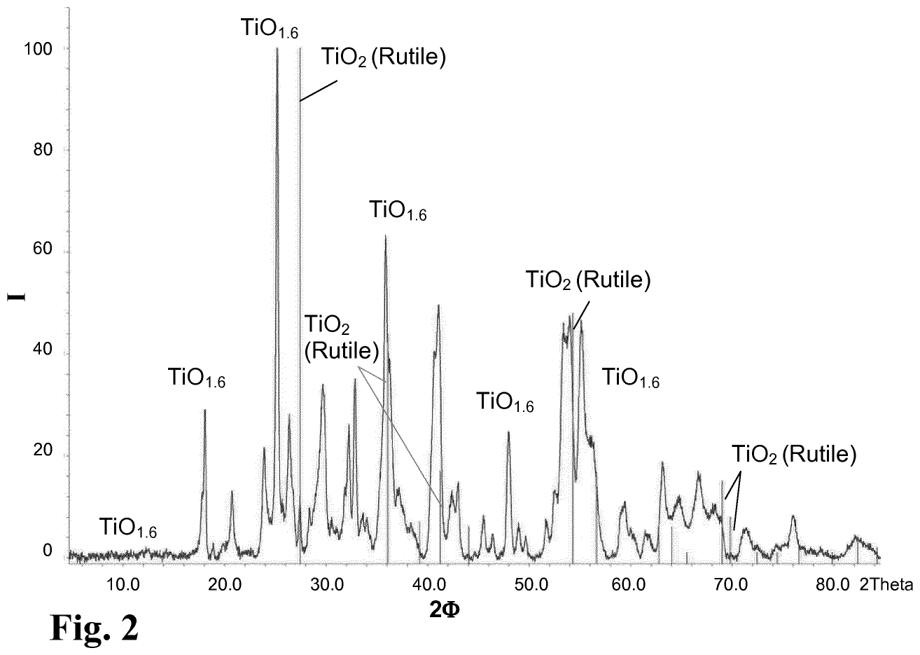

FIG. 2 shows an X-ray diffraction diagram of a target layer material according to the invention in combination with the typical deflection signals of TiO₂ in its rutile crystalline phase.

### PREPARATION OF SPUTTERING TARGET

As feedstock material a non-stoichiometric oxygen deficient titania powder was provided having a particle size in the range of from 25-125 μm. The degree of sub-stoichiometry is represented in the formula TiOy by y˜1.4.

A stainless steel tube was provided with an of outer diameter of 133 mm and an inner diameter of 125 mm. Suitable lengths of the substrate tube are in the range between 500 to 4.000 mm. The tube was coated with a rough Ni layer. The coated stainless steel tube was used as a substrate for depositing a target material by plasma spraying, whereby the rough Ni undercoating acts a bonding layer for the target material.

For plasma spraying the TiOy feedstock materials, a water-cooled plasma torch device was used. The plasma torch was operated with a mixture of hydrogen and argon with variable mixing ratio. The hydrogen/argon mixing ratio determines the reduction/oxidation state of the plasma; details about the mixing ratio used in the examples are provided further below. The process gas may also contain Helium. The sub-stoichiometric TiOy powder was injected via a carrier gas directly into the plasma flame. The powder feed rate is set at a value in the region between 50 g/min and 350 g/min.

The sub-stoichiometric titanium dioxide coated on the substrate is solidified under conditions which prevent it from regaining oxygen and reconverting to TiO₂. Especially at high feed rates or at high power levels the substrate may be cooled (e.g. gas cooling on outside or water cooling on the inside to 35° C.) during the plasma spraying in order to quench the titanium dioxide in its deposited sub-stoichiometric form. A TiOx target material layer with a thickness of more than 10 mm is prepared, whereby in the formula TiOx the grade of sub-stoichiometry is represented by x≥1.54 and x≤1.81 (see table 1). The resulting sputtering target comprises the substrate and the target layer of TiOx.

### EXAMPLE 1

A rotatable substrate tube with a tube length of 550 mm was provided comprising a backing tube of stainless steel of outer diameter 133 mm, inner diameter 125 mm, length 550 mm. The outer cylinder surface was coated with a Ni layer.

It was water cooled on the inside to 35° C. and thereby coated by plasma spraying with a powder of sub-stoichiometric titanium oxide (TiOy, whereby y=1,69) having a particle size of from 40 to 90 μm using argon as the primary plasma gas and hydrogen as the secondary plasma gas (70 vol.-% argon, 30 vol.-% hydrogen). The power level was 60 kW (400 Å).

The resulting target layer has a thickness of from 11 mm and it consists of sub-stoichiometric titanium dioxide (TiOx, where x is 1.71, see Table 1). The subsequently performed ethanol visualization test shows that it is crack free. The hammer impact test shows strong adhesion of the target material to the substrate tube and less susceptibility to cracking compared to comparative example 1.

The process for production of the sputter target was repeated several times but target layers of 12 mm and more were produced instead a target layer thickness of 11 mm. The ethanol visualization test showed a crack free layer which could be produced with high reproducibility for a maximum layer thickness of 11 mm.

### EXAMPLE 2

Example 1 was repeated using a starting powder of sub-stoichiometric titanium oxide (TiOy, whereby y=1.40) having a particle size of from 5 to 45 μm was used as the feedstock material. Argon was used as the primary plasma gas and hydrogen as the secondary plasma gas (70 vol.-% argon, 30 vol.-% hydrogen). The power level was the same as in Example 1.

The resulting target layer has a thickness of from 14 mm and it consists of sub-stoichiometric titanium oxide (TiOx, where x is 1.63). When spraying onto a target base under the conditions of Example 2 the TiO_{y} was converted into a sub-stoichiometric rutile form of titanium dioxide. The subsequently performed ethanol visualization test shows that it is crack free. The hammer impact test shows strong adhesion of the target material to the substrate tube and less susceptibility to cracking compared to comparative example 1.

The process for production of the sputter target was repeated several times but target layers of 15 mm and more were produced instead a target layer thickness of 14 mm. The ethanol visualization test showed a crack free layer could be produced with high reproducibility for a maximum layer thickness of 14 mm.

### EXAMPLE 3

Example 1 was repeated using a powder of sub-stoichiometric titanium oxide (TiOy, whereby y=1.32) having a particle size of from 40 to 90 μm. Argon was used as the primary plasma gas and hydrogen as the secondary plasma gas (70 vol.-% argon, 30 vol.-% hydrogen). The power level was the same as in Example 1.

The resulting target layer has a thickness of from 18 mm and it consists of sub-stoichiometric titanium oxide (TiOx, where x is 1.54). On spraying onto a target base under the conditions of Example 2 the TiO₂ was converted into a sub-stoichiometric rutile form of titanium dioxide.

### EXAMPLE 4

Example 3 was repeated using a rotatable substrate tube with a tube length of 2000 mm. The resulting target layer has a thickness of from 16 mm and it consists of sub-stoichiometric titanium oxide (TiOx, where x is 1.53).

### EXAMPLE 5

Example 3 was repeated using a rotatable substrate tube with a tube length of 3852mm. The resulting target layer has a thickness of from 15 mm and it consists of sub-stoichiometric titanium oxide (TiOx, where x is 1.54).

### COMPARATIVE EXAMPLE 1

Example 1 was repeated using a powder of sub-stoichiometric titanium oxide (TiOy, whereby y=1.81) having a particle size of from 40 to 90 μm. Argon was used as the primary plasma gas and hydrogen as the secondary plasma gas (70 vol.-% argon, 30 vol.-% hydrogen). The power level was the same as in Example 1.

The resulting target layer has a thickness of from 11 mm and it consists of sub-stoichiometric titanium oxide (TiOx, where x is 1.82). When spraying onto a target base under the conditions of Example 2 the TiOy feedstock particles were converted into a sub-stoichiometric TiOx. The mayor phase is Ti₉O₁₇ and it includes small amounts of the rutile form and the anatase form of titanium dioxide (see Table 1).

Cracks occur in the target material.

Therefore, the production of the sputter target according to Comparative Example 1 was repeated, but instead of a layer thickness of 11 mm, the target material deposition was stopped at a layer thickness of 10 mm and less. The ethanol visualization test showed a crack free layer which could be produced with high reproducibility only for a maximum layer thickness of 10 mm.

TABLE 1

| | | | | | | | | Stoechio- | Stoe- | Maximal |
|---|---|---|---|---|---|---|---|---|---|---|
| | Short nomination | TiO₂ | TiO₂ | | | | | chiometry | chiometry | crack free |
| | in | Anatase | Rutile | Ti₉O₁₇ | Ti₄O₇ | Ti₃O₅ | Hardnes | Powder | Target | layer thickness |
| Example | the specification | Vol.-% | Vol.-% | Vol.-% | Vol.-% | Vol.-% | HV10 | (y-value) | (x-value) | (mm) |
| 1 | TiO_{1,7} | 0 | 4.0 | 24 | 32 | 40 | 520 | 1.69 | 1.71 | 11 |
| 2 | TiO_{1,6} | 0 | 2.0 | 0 | 42 | 56 | 480 | 1.40 | 1.63 | 14 |
| 3 | TiO_{1,5} | 0 | 1.0 | 0 | 40 | 59 | 450 | 1.32 | 1.54 | 18 |
| Comp. 1 | TiO_{1,8} | 1.0 | 6.0 | 93 | 0 | 0 | 570 | 1.82 | 1.81 | 10 |

The results of the XRD measurement are shown in FIGS. 1 and 2 and summarized in Table 1.The major phases of the target material of Examples 1 to 3 are Ti₃O₅ and Ti₄O₇. The total volume share of these phases is at least 75 vol.-%. In the qualitatively best sample (Example 3) the total share of these phases is even 99 vol.-%. The ratio of the volume shares of the phases Ti₃O₅/Ti₄O₇ calculated on the basis of the XRD graph is 0.59/0.40=1.48.

The TiO_{1.8} material (Comp. Example 1) shows cracks and delaminating when the layer thickness of the target material is higher than 10 mm. That maximal crack free target layer thickness made of TiO_{1.8} material is significantly lower than that which can be achieved with target materials TiO_{1.6} and TiO_{1.5} Due to the absence of the phases Ti₃O₅ and Ti₄O₇ a volume ratio of those phases cannot be calculated.

In the XRD analysis diagram of FIG. 1 the measured defracted intensity I (in relative units; %) of sample 2 (TiO_{1.6}) is plotted against diffraction angle 2theta. It shows that Ti₃O₅ and Ti₄O₇ are the major phases of the microstructure. In addition to that the XRD analysis diagram of FIG. 2 shows that the microstructure of said TiO1.6 sample has no defraction signal line that can be clearly contributed to TiO₂ in its rutile crystalline form.

1. A cylindrical sputter target comprising a substrate and a target material that forms a layer on the substrate, said layer has a thickness d, wherein the target material comprises TiOx as the main component, and x is within a range of 1<x<2, and characterized in that d is larger than 10 mm and x is within a range of 1.45<x<1.7, wherein the target material is free from visible surface cracks, or if surface cracks exist, they have a maximum length of less than 1 cm.

2. The sputtering target according to claim 1, wherein d is at least 12 mm.

3. The sputtering target according to claim 1, wherein 1.50 <x <1.65.

4. The sputtering target according to claim 1, wherein the target material has a Vickers hardness HV, wherein HV<500 HV10.

5. The sputtering target according to claim 1, wherein the target material comprises a Ti₄O₇ phase in a concentration of at least 30 vol.-%, and a Ti₃O₅ phase in a concentration of at least 40 vol.-%.

6. The sputtering target according to claim 1, wherein the target material comprises a Ti₄O₇ phase and Ti₃O₅ phase in a total concentration of at least 75 vol. %.

7. The sputtering target according to claim 1, wherein the target material comprises a Ti₃O₅ phase in a first concentration (in vol.-%) and a Ti₄O₇ phase in a second concentration (in vol.-%), wherein the ratio of first concentration and second concentration Ti₃O₅/Ti₄O₇ is at least 1.2.

8. The sputtering target according to claim 1, wherein the target material comprises an Anatase phase of TiO₂ in a total concentration of less than 1 vol.-%.

9. (canceled)

10. Sputtering target according to claim 1, wherein the target material comprises a homogeneous degree of sub-stoichiometry, in the sense that the degree of sub-stoichiometry of ten samples of 10 g each has a standard deviation in the of sub-stoichiometry degree of less than ±5%.

11. A process for producing a sputtering target, which comprises
(a) providing a substrate made of a metal or alloy,
(b) providing a ceramic powder comprising a metal oxide powder of the chemical formula TiOy as the main component, whereby TiOy is deficient in oxygen as compared with the stoichiometric composition TiO₂,
(c) forming a ceramic layer on the substrate by plasma spraying, wherein said ceramic powder is made in a semi-molten state in a high temperature plasma gas in a reducing atmosphere, and it is transported and deposited onto the substrate by the plasma gas so as to obtain a target comprising a layer with a thickness d of a target material that comprises TiOx as the main component, whereby TiOx is deficient in oxygen as compared with the stoichiometric composition TiO₂,
wherein y in said metal oxide powder TiOy is within a range of 1.3<y<1.7, and wherein x in said target material TiOx is within a range of 1.45<x<1.7, and the layer thickness d is more than 10 mm.

12. The process according to claim 11, wherein the thickness d is at least 12 mm, and wherein 1.50<x<1.65.

13. The process according to claim 11, wherein a cylindrical substrate is used as the substrate.

14. The process according to claim 11, wherein providing the ceramic powder according to method step (b) comprises providing an oxygen deficient titania powder having a particle size in the range of from 25-125 μm.

15. A cylindrical sputtering target provided by a process according to claim 10.

16. The sputtering target according to claim 1, wherein d is at least 14 mm.

17. The sputtering target according to claim 1, wherein 1.50<x<1.55.

18. The sputtering target according to claim 1, wherein the target material has a Vickers hardness HV, wherein HV<475 HV10.

19. The sputtering target according to claim 1, wherein the target material comprises a Ti₄O₇ phase and Ti₃O₅ phase in a total concentration of at least 99 vol.-%.

20. The sputtering target according to claim 1, wherein the target material comprises a Ti₃O₅ phase in a first concentration (in vol.-%) and a Ti₄O₇ phase in a second concentration (in vol.-%), wherein the ratio of first concentration and second concentration Ti₃O₅/Ti₄O₇ is at least >1.4.

21. The process according to claim 11, wherein the thickness d is at least 14 mm, and wherein 1.50<x<1.55.

22. The process according to claim 11, wherein providing the ceramic powder according to method step (b) comprises providing an oxygen deficient titania powder having a particle size in the range of from 40-90 μm.
